(19) United States
(12) Patent Application Publication
(10) Pub. No.: US 2024/0243072 A1
(43) Pub. Date: Jul. 18, 2024

(54) Integrated Circuitry, Memory Circuitry Comprising Strings Of Memory Cells, And Methods Used In Forming Integrated Circuitry

(71) Applicant: Micron Technology, Inc., Boise, ID (US)

(72) Inventors: Kar Wui Thong, Boise, ID (US); Harsh Narendrakumar Jain, Boise, ID (US); Richard T. Housley, Boise, ID (US); Manampurathu Sivaramapanicker Suresh Kumar, Singapore (SG)

(73) Assignee: Micron Technology, Inc., Boise, ID (US)

(21) Appl. No.: 18/408,194

(22) Filed: Jan. 9, 2024

Related U.S. Application Data
(60) Provisional application No. 63/438,685, filed on Jan. 12, 2023.

(51) Int. Cl. H01L 23/544

(52) U.S. Cl. CPC H01L 23/544; H01L 2223/54426; H01L 2223/5446; H10B 43/27

(57) ABSTRACT

A method used in forming integrated circuitry comprises forming a stack comprising vertically-alternating first tiers and second tiers. The first tiers comprise sacrificial material and the second tiers comprise non-sacrificial material that is of different composition from that of the sacrificial material. The stack extends from individual die areas to and across scribe-line area that is between immediately-adjacent of the individual die areas. The scribe-line area comprises a horizontal area in which a registration mark or an alignment mark is being fabricated. Horizontally-spaced features of the registration mark or of the alignment mark are simultaneously formed in the first tiers and the second tiers in the horizontal area and in the individual die areas. The horizontally-spaced features in the horizontal area are grouped in sections that are horizontally-separated by gaps in at least one vertical cross-section where there are less, if any, such horizontally-spaced features than are in the sections. Horizontally-spaced vertical slots are formed through uppermost of the first and second tiers of the stack in the horizontal area of the registration mark or of the alignment mark. Through the horizontally-spaced vertical slots, the sacrificial material is replaced with metal material. After the replacing, the first and second tiers in the scribe-line areas are cut through to form individual die that individually comprise one of the individual die areas. Other embodiments, including structure, are disclosed.

### TECHNICAL FIELD

Embodiments disclosed herein pertain to integrated circuitry, to memory circuitry comprising strings of memory cells, and to methods used in forming integrated circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

Integrated circuitry such as memory circuitry described above is commonly manufactured in a sequence of patterning steps of one or more layers formed over a substrate such as a semiconductor wafer. Thereby, electronic components of the circuitry (e.g., transistors, capacitors, conductive vias, etc.) made of various materials are deposited onto the substrate in layers and patterned individually or multiple layers at a time. The separate patterning steps need to be aligned correctly relative one another, for example using a process commonly referred to as lithography. The semiconductor wafer is typically fabricated to have a plurality of individual die areas that are separated by scribe-line area. Each die area is fabricated to ultimately contain a complete integrated circuit that at the conclusion of processing is isolated by cutting through the scribe-line area to form individual integrated circuit chips (die) from the former interconnected individual die areas.

In patterning within the individual die areas, using lithography for example, a masking tool (e.g., a reticle) and the semiconductor wafer must be precisely x-y aligned relative one another. Patterns are typically formed in the scribe-line area which are examined by the lithography equipment for achieving proper x-y alignment and for determining whether acceptable x-y alignment was achieved. One of such patterns is commonly known as an alignment mark. Multiple of these would typically be placed within the scribe-line area and individually include a plurality of features for which the lithography equipment can optically scan to determine and modify x-y alignment of the wafer and masking tool prior to patterning. Another of such patterns is commonly known as a registration mark. Multiple of these would also typically be formed in the scribe-line area, with the lithography equipment being used to optically scan the registration marks to determine whether proper x-y alignment was achieved after the patterning.

### BRIEF DESCRIPTION OF THE DRAWINGS

FIG. 1 is a diagrammatic top plan view of a substrate in process in accordance with an embodiment of the invention.

FIG. 2 is an enlargement of a portion of FIG. 1.

FIGS. 3 and 5 are enlargements of portions of FIG. 2.

FIGS. 4 and 6-41 are diagrammatic sequential sectional, expanded, enlarged, and/or partial views of the construction of FIGS. 1-3 and 5, or portions thereof, and/or alternate embodiments in process in accordance with some embodiments of the invention.

### DETAILED DESCRIPTION OF EXAMPLE EMBODIMENTS

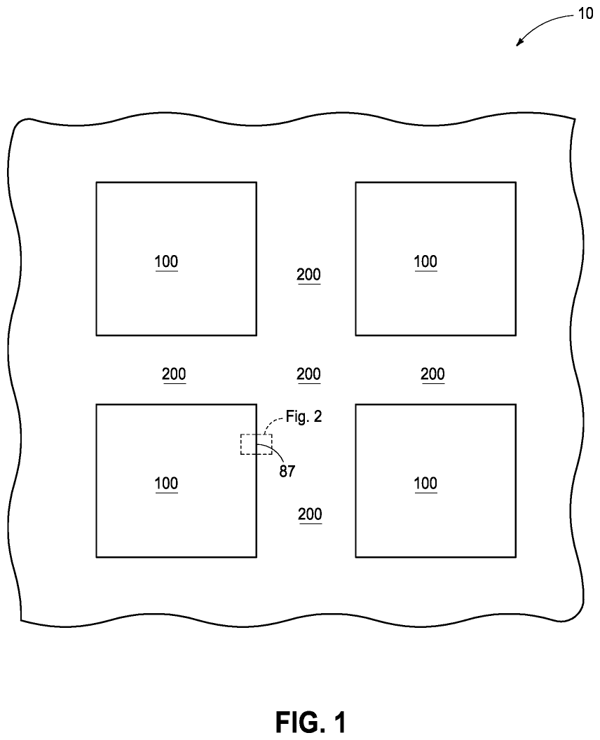

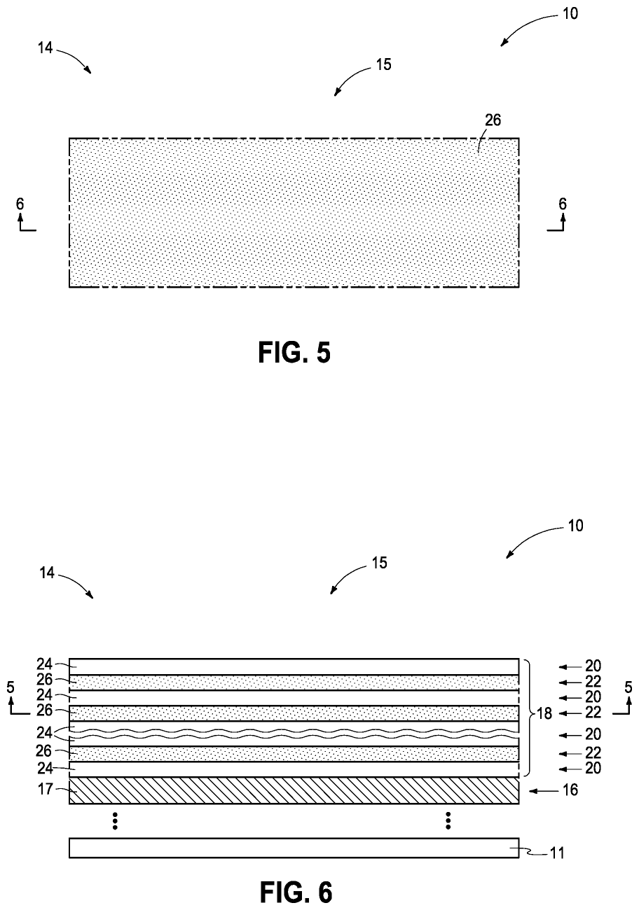

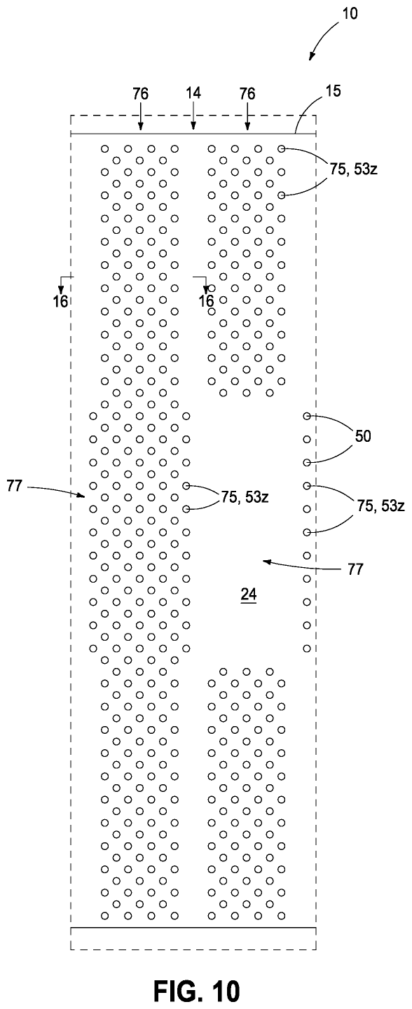

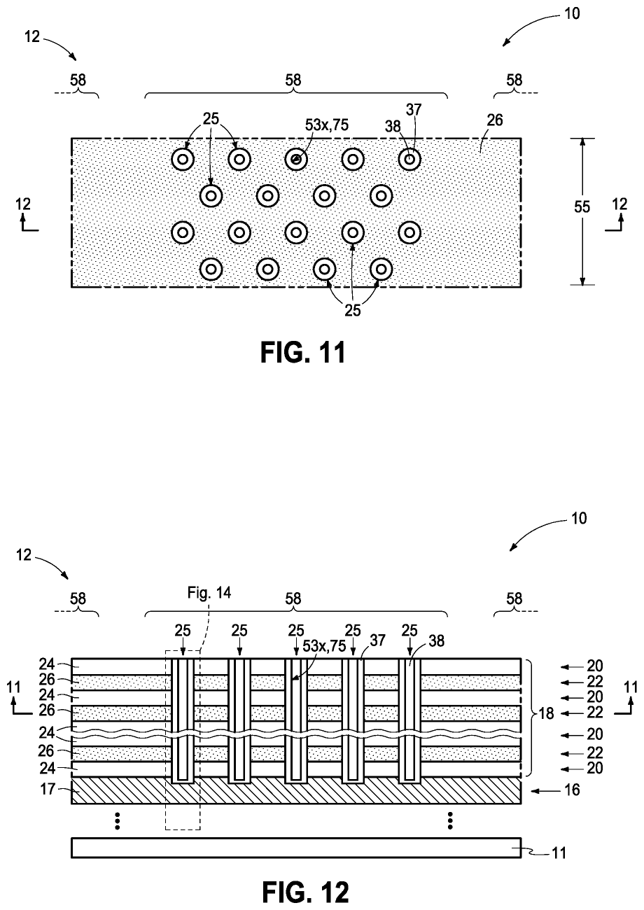

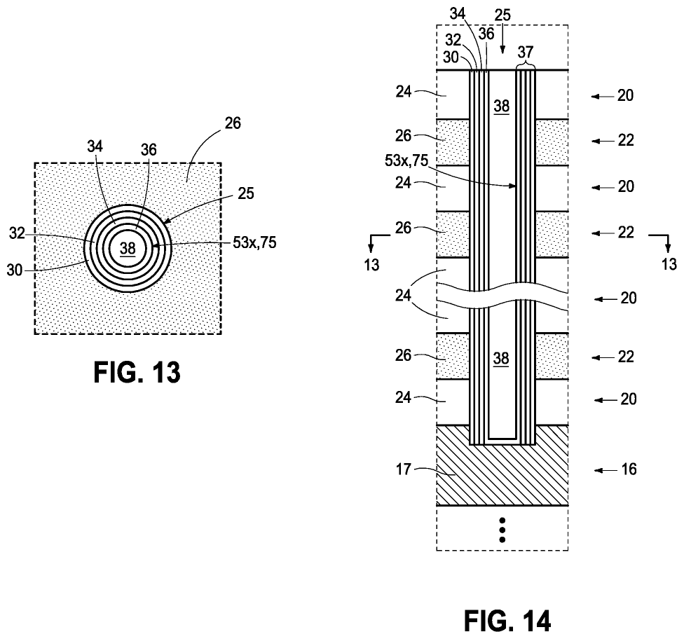

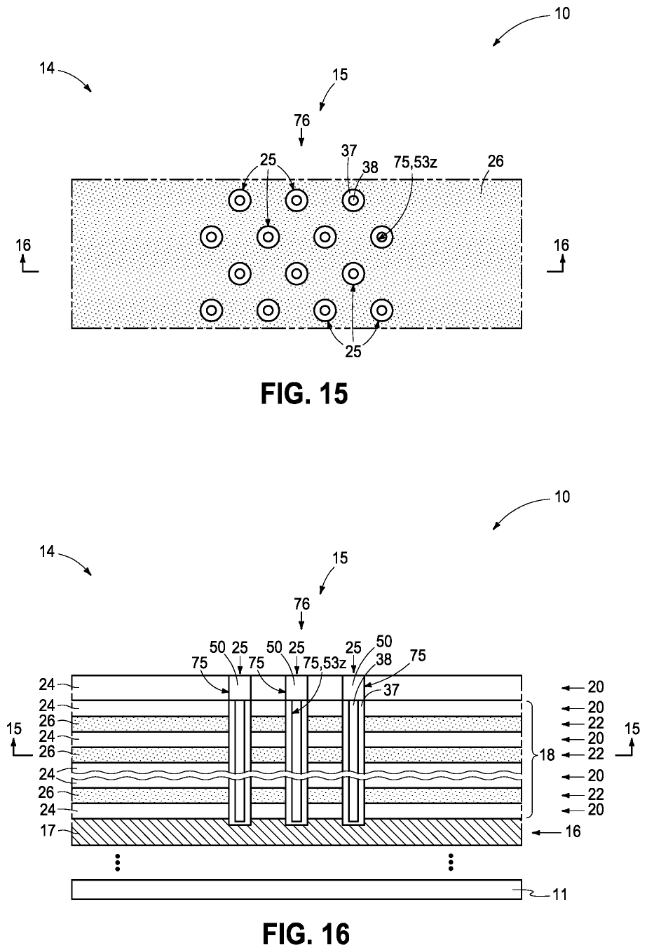

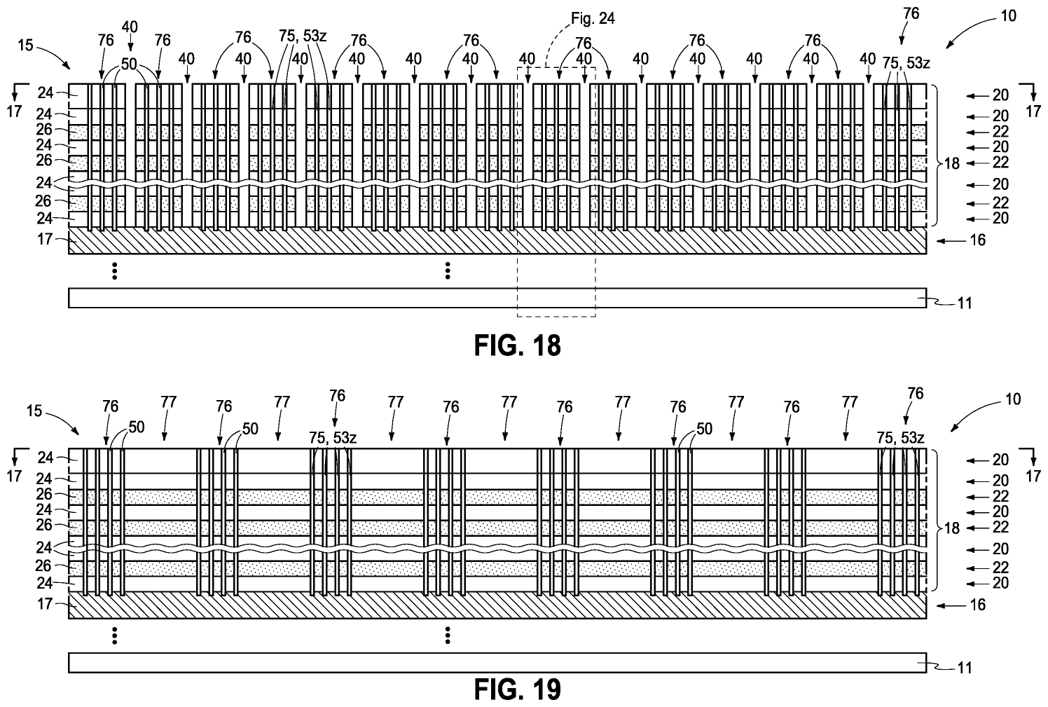

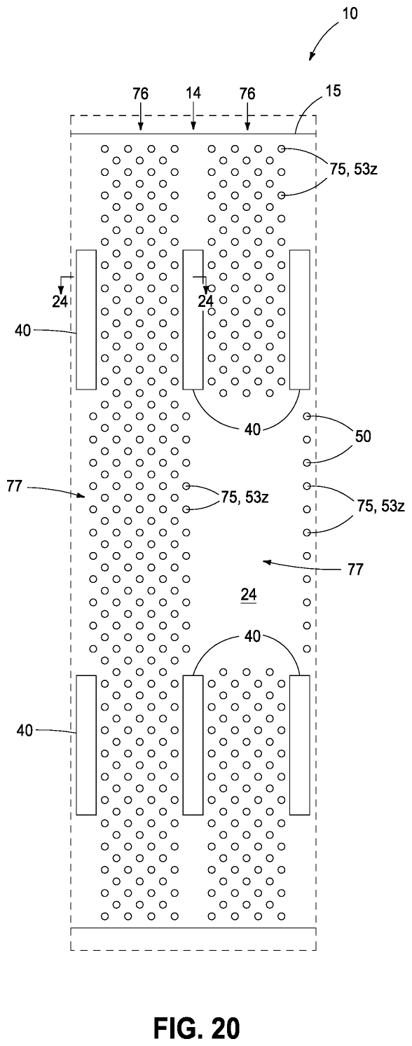

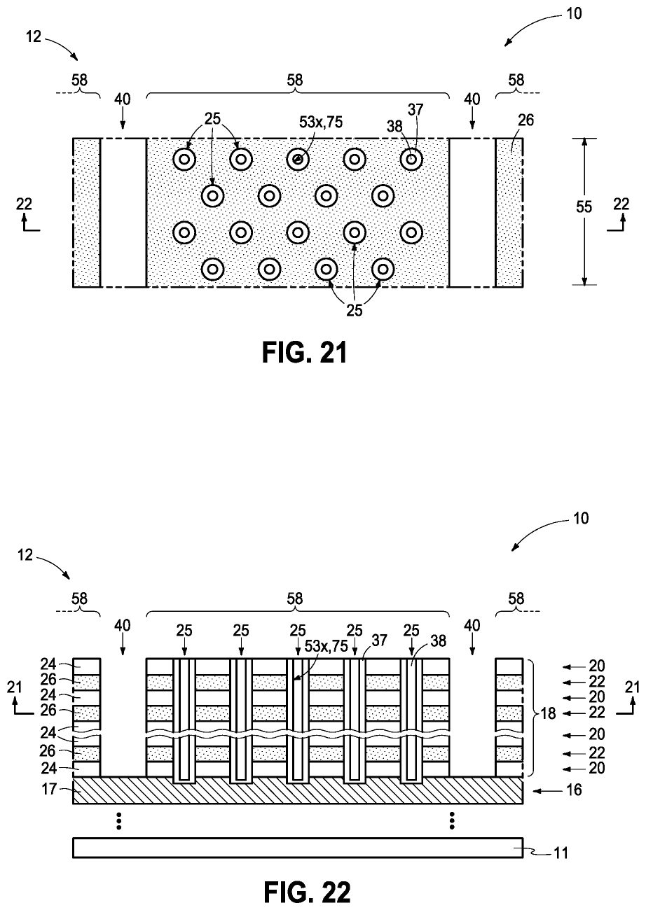

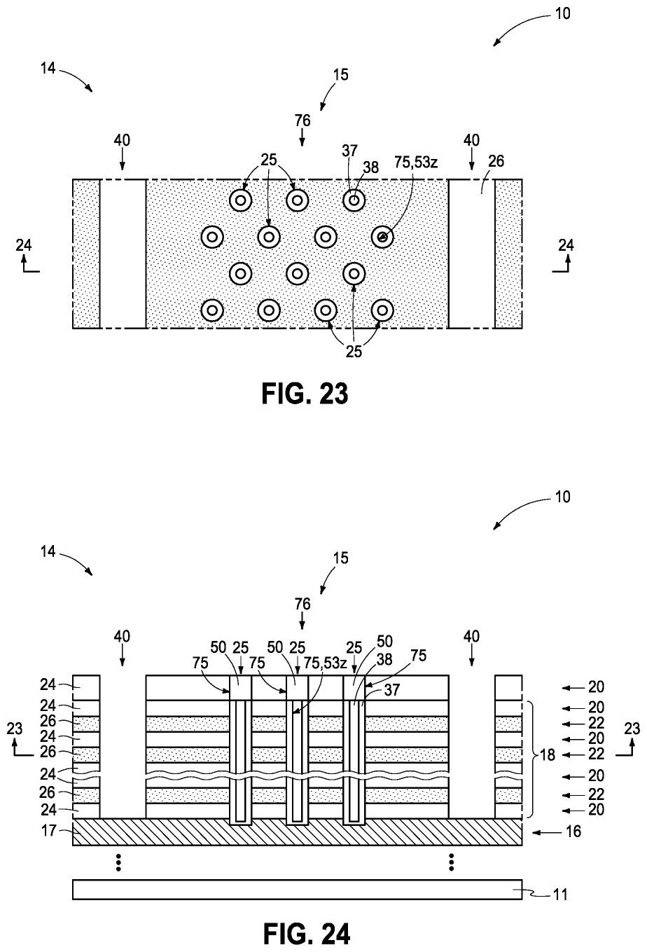

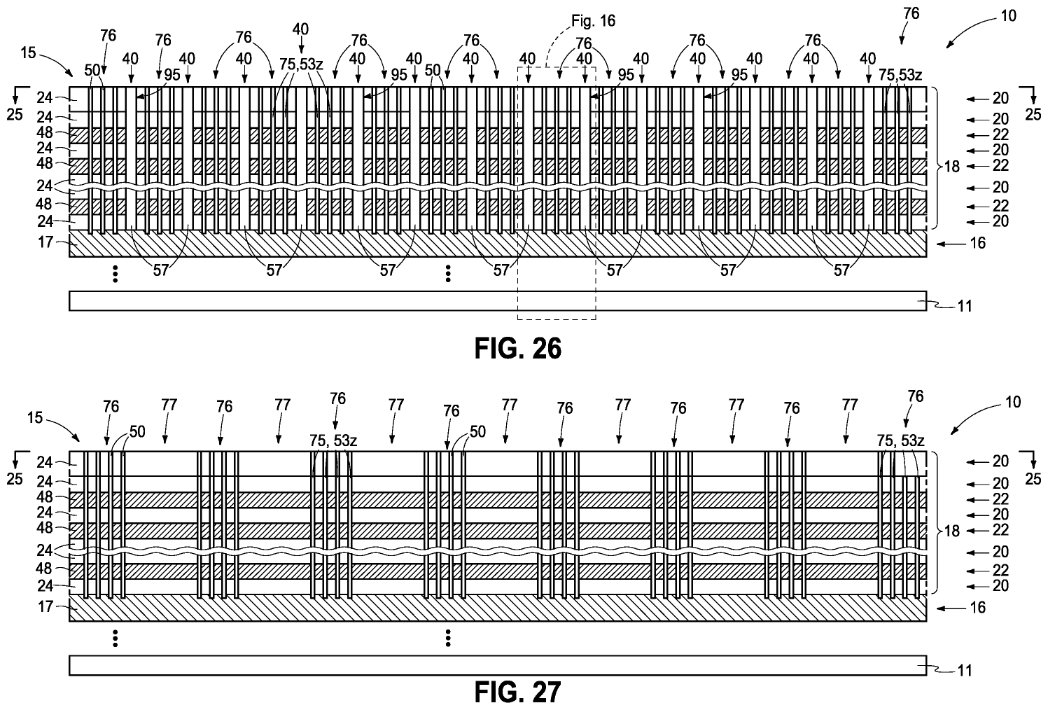

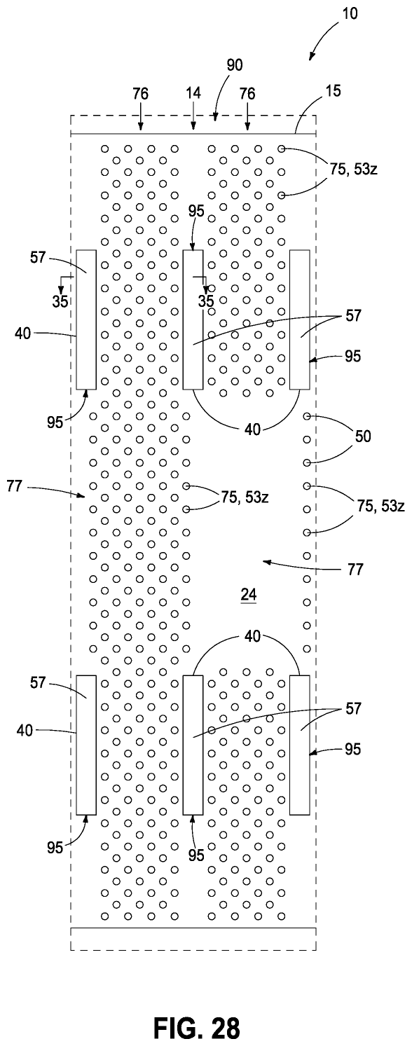

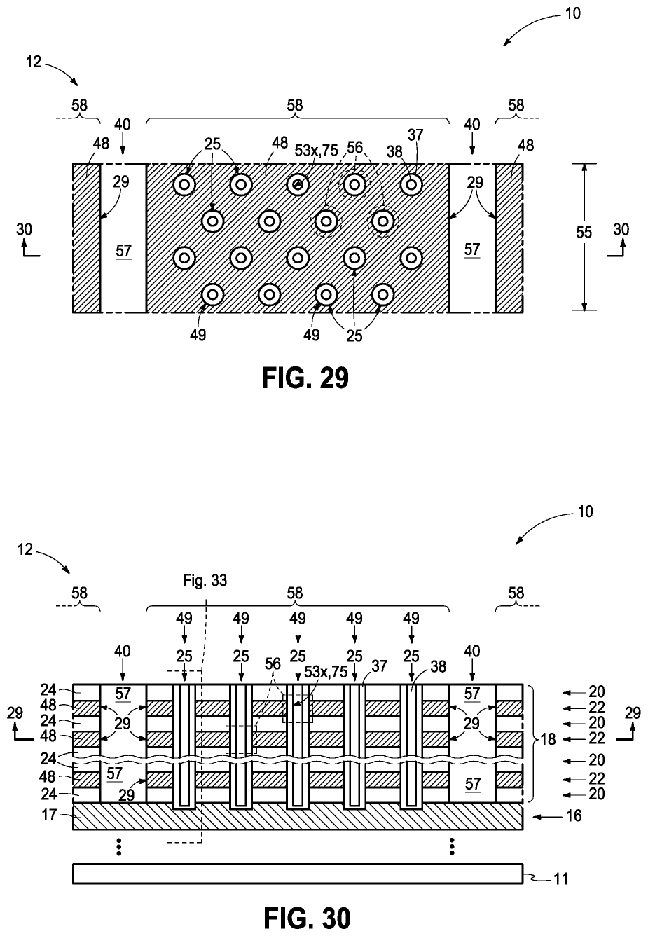

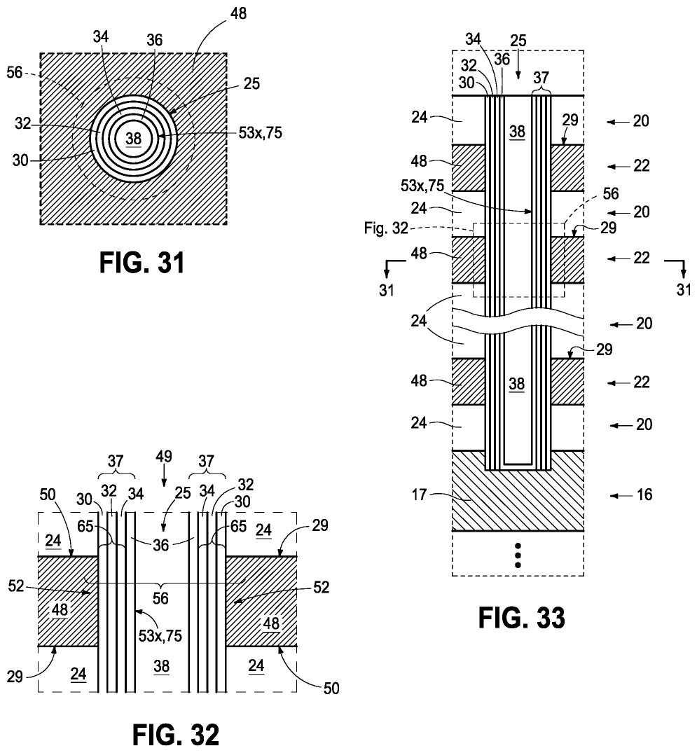

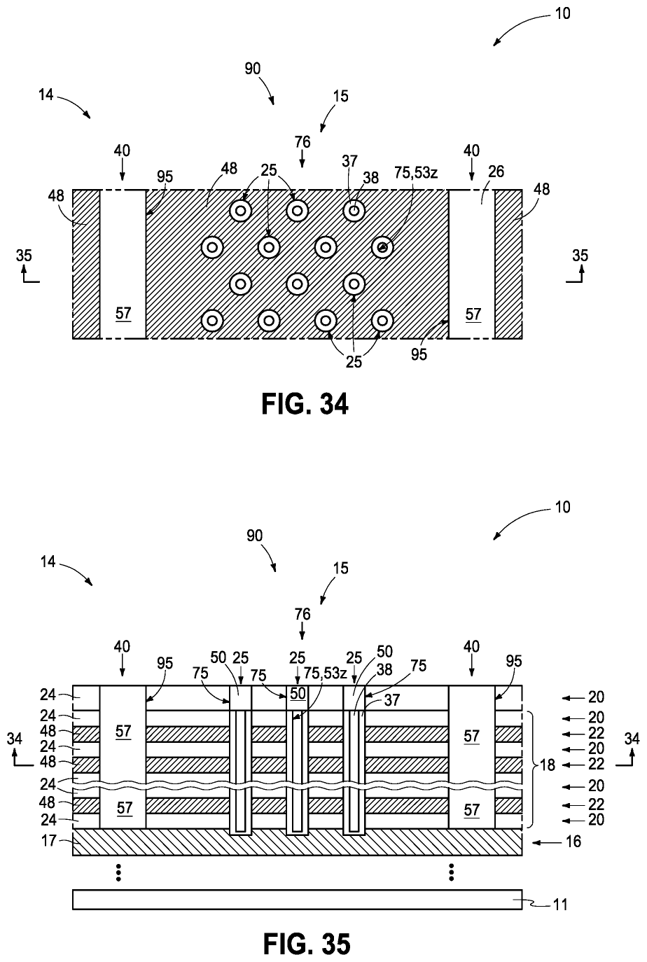

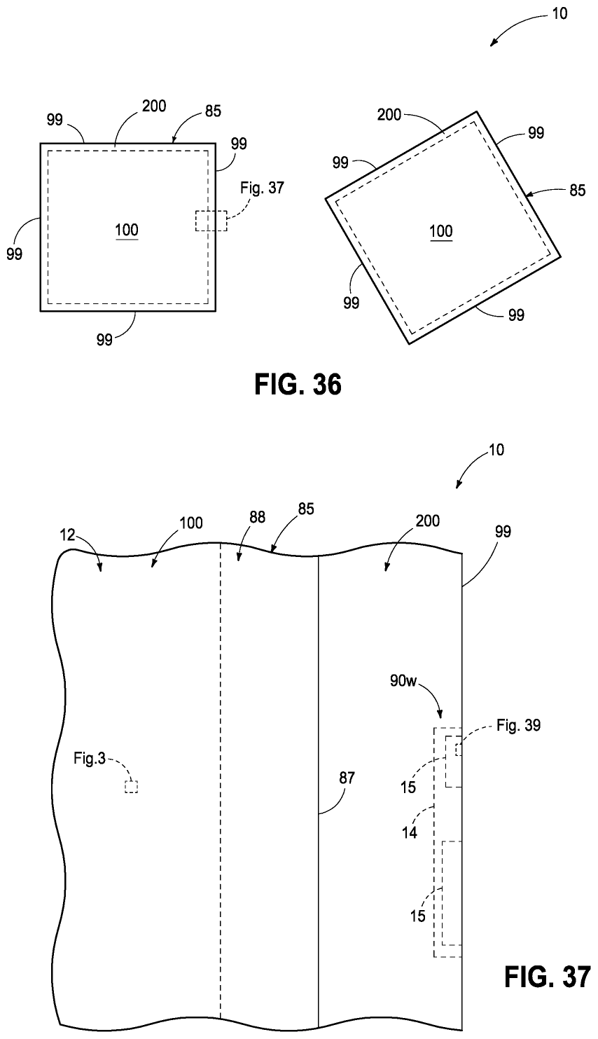

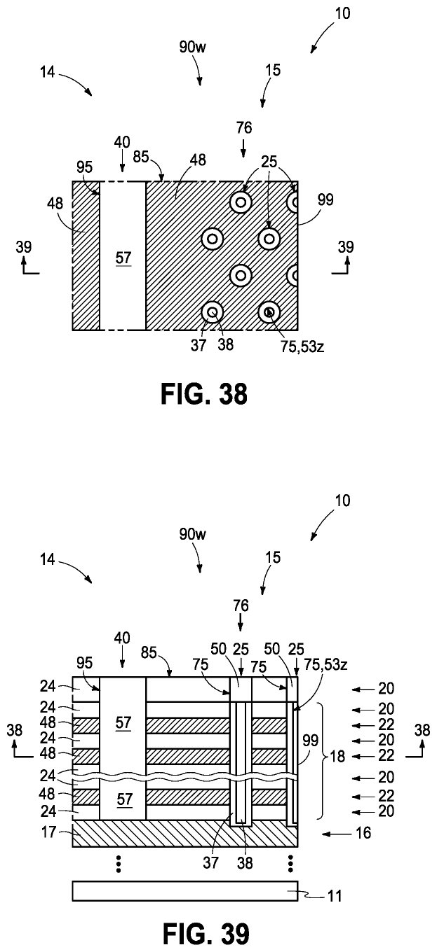

Embodiments of the invention encompass methods of forming integrated circuitry and integrated circuitry regardless of method of manufacture. One example form of such integrated circuitry is memory, although not all aspects of the inventions disclosed herein are so limited. Example methods of forming integrated circuitry are described with reference to FIGS. 1-41.

Referring to FIG. 1, such shows a portion of a construction 10 (e.g., a portion of a semiconductor wafer) comprising individual die areas 100 having scribe-line area 200 there-between. A registration mark or an alignment mark will be fabricated in scribe-line area 200, with likely multiple such registration marks and/or alignment marks being fabricated. Multiple such marks may be fabricated that may be of the same or different configuration(s) relative one another, with the discussion largely proceeding with respect to fabrication of a single registration mark or a single alignment mark.

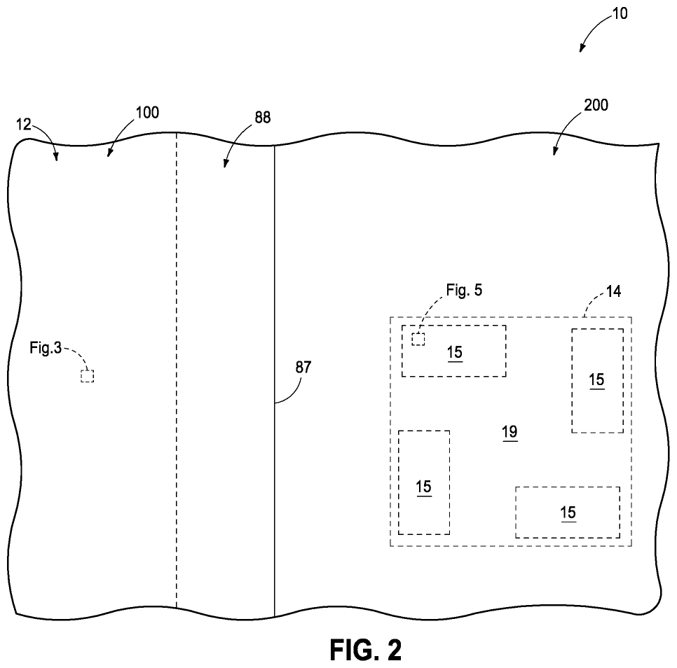

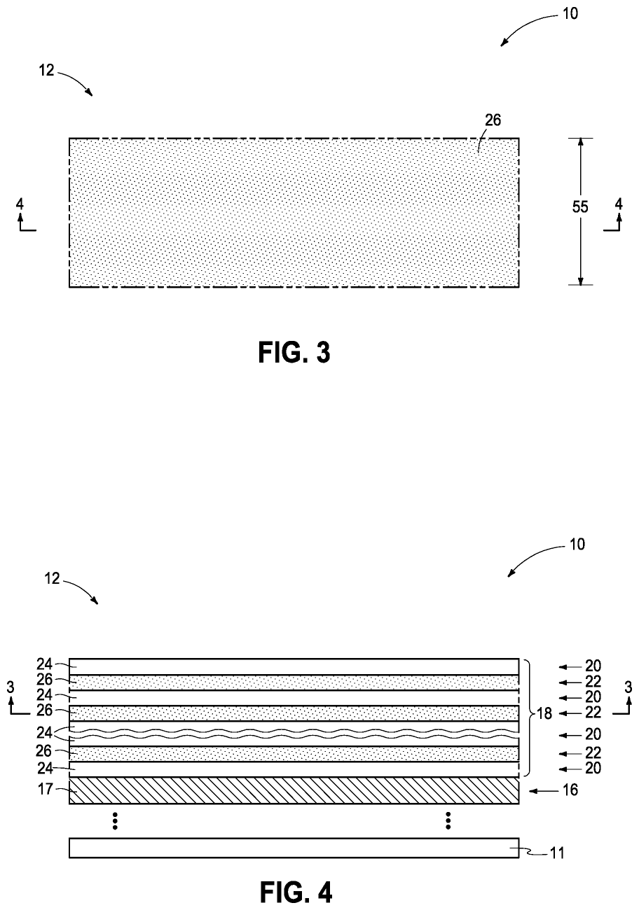

Referring to FIGS. 2-6, such are enlarged views of a portion of FIG. 1 showing a die area 100 and an immediately-adjacent scribe-line area 200. In the example embodiment, memory circuitry comprising strings of memory cells are being fabricated. Embodiments of the invention encompass so-called “gate-last” or “replacement-gate” processing, so-called “gate-first” processing, and other processing whether existing or future-developed independent of when transistor gates are formed. Embodiments of the invention also encompass integrated circuitry such as that comprising a memory array comprising strings of memory cells (e.g., NAND architecture) independent of method of manufacture. Construction 10 comprises a base substrate 11 (e.g., part of a semiconductor wafer) that may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-6-depicted materials. For example, other partially or wholly fabricated components of integrated circuitry may be provided somewhere above, about, or within base substrate 11. Control and/or other peripheral circuitry for operating components within an array (e.g., a memory array) may also be fabricated and may or may not be wholly or partially within an array or sub-array. Further, multiple sub-arrays may also be fabricated and operated independently, in tandem, or otherwise relative one another. As used in this document, a “sub-array” may also be considered as an array.

Example construction 10 comprises a conductor tier 16 comprising conductor material 17 (e.g., WSiₓ under conductively-doped polysilicon) above substrate 11. Conductor tier 16 may comprise part of control circuitry (e.g., peripheral-under-array circuitry and/or a common source line or plate) used to control read and write access to the transistors and/or memory cells in an array 12. In an embodiment where the integrated circuitry being fabricated will comprise memory circuitry, example array 12 is a memory-array region 12 within individual die areas 100. Such may be juxtaposed relative to the edge(s) of individual die areas 100 (not shown) or be laterally-spaced therefrom (as shown), for example a space 88 being between array region 12 and an edge 87 of die area 100.

A stack 18 comprising vertically-alternating first tiers 22 and second tiers 20 is directly above conductor tier 16, with first tiers 22 comprising sacrificial material 26 (e.g., silicon nitride) and second tiers 20 comprising non-sacrificial material 24 that is of different composition from that of sacrificial material 26 (e.g., silicon dioxide). In some embodiments, first tiers 22 may be referred to as conductive tiers 22 and second tiers 20 may be referred to as insulative tiers 20, with first tiers 22 being conductive and second tiers 20 being insulative at least in a finished-circuitry construction in some embodiments. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the first tiers 22 and/or above an uppermost of the first tiers 22. For example, one or more select gate tiers (not shown) may be between conductor tier 16 and the lowest first tier 22 and one or more select gate tiers may be above an uppermost of first tiers 22 (not shown). Alternately or additionally, at least one of the depicted uppermost and lowest first tiers 22 may be a select gate tier.

Stack 18 extends from individual die areas 100 to and across scribe-line area 200 that is between immediately-adjacent individual die areas 100. The example-depicted scribe-line area 200 comprises a horizontal area 14 in which a registration mark or an alignment mark is being fabricated. Multiple such registration and/or alignment marks would likely be formed, with the discussion largely proceeding with respect to a single registration or alignment mark. In one embodiment and as shown, horizontal area 14 comprises horizontally-spaced horizontal regions 15 of the mark being fabricated and horizontal space 19 between immediately-adjacent horizontal regions 15 (e.g., “among” when more than two regions 15).

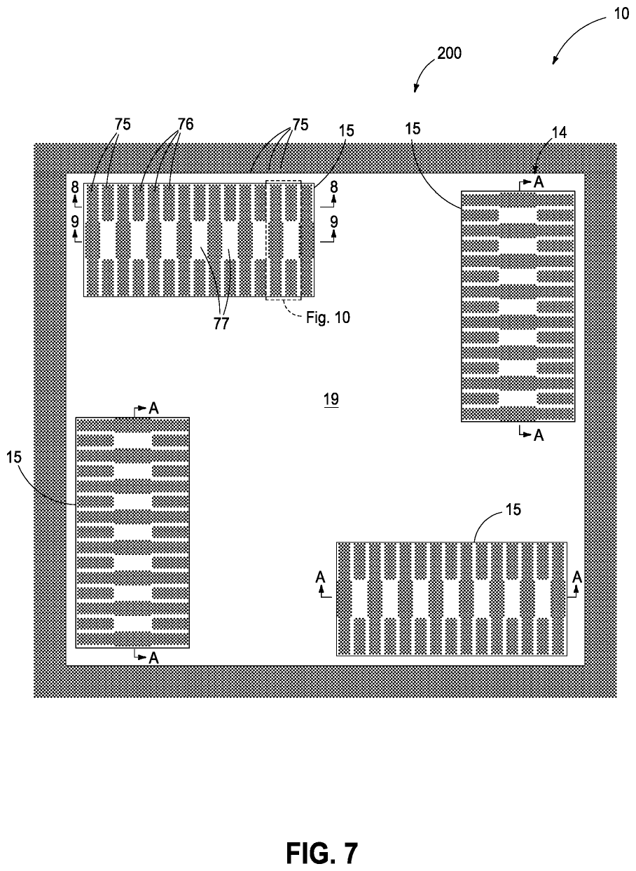

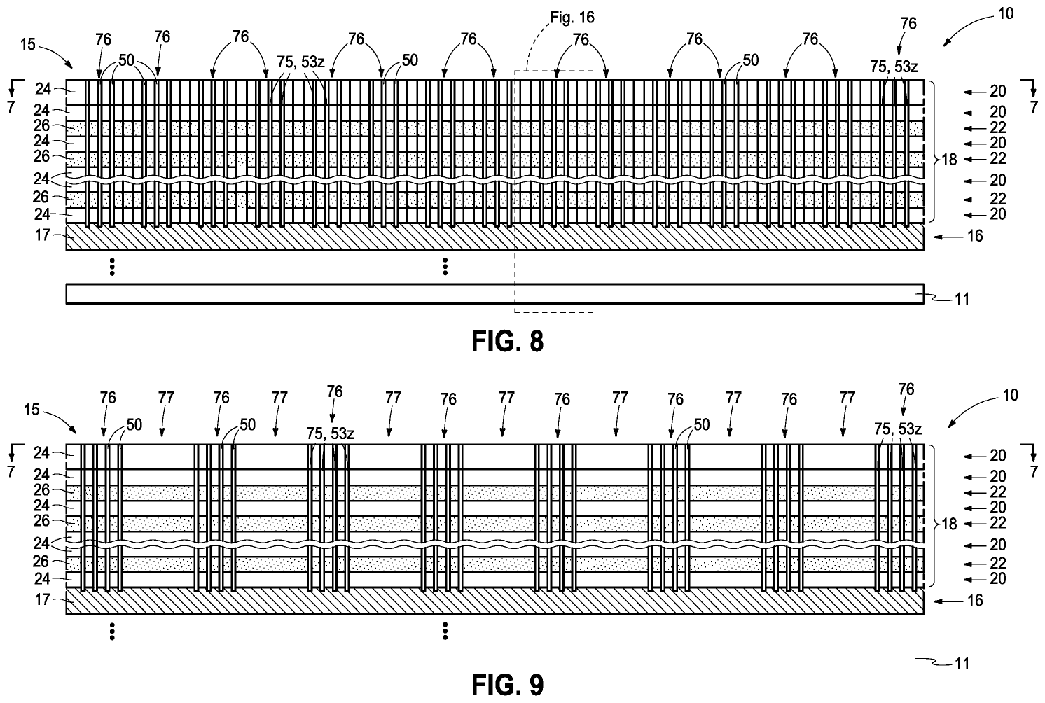

Referring to FIGS. 7-16, horizontally-spaced features 75 of the registration mark or of the alignment mark being fabricated have simultaneously been formed in first tiers 22 and second tiers 20 in horizontal area 14 and in individual die areas 100 (e.g., in array 12). For convenience and clarity in the figures, horizontal-scale has been reduced FIGS. 8 and 9 compared to FIGS. 3-6 while vertical-scale has not been reduced. Horizontally-spaced features 75 in horizontal area 14 are grouped in sections 76 that are horizontally-separated by gaps 77 in at least one vertical cross-section (e.g., that of FIG. 9) where there are less, if any, such horizontally-spaced features than there are in sections 76. FIGS. 7 and 9 show an example wherein no horizontally-spaced features 75 have been formed in gaps 77. In the depicted example embodiment, sections 76 and gaps 77 have been formed in individual horizontal regions 15, with the at least one vertical cross-section being with respect to a respective one of individual horizontal regions 15 (e.g., example respective cut lines A-A that would be identical in vertical cross-sections to that depicted by FIG. 9).

In one embodiment and as shown, the horizontally-spaced features formed in individual die areas 100 comprise operative (in the finished-circuitry construction) channel-material strings 53x (e.g., comprising channel material 36) of memory cells and that extend through first and second tiers 22, 20 in openings 25 in memory-array region 12 in the finished-circuitry construction. Further in such embodiment, horizontally-spaced features 75 of the registration mark or the alignment mark being fabricated comprise dummy (meaning always inoperative) channel-material strings 53z. Example features 75 comprising example channel-material strings 53ₓ, 53_{z} may taper radially-inward and/or radially-outward moving deeper and stack 18 and may be vertical (as shown) or angled slightly from vertical (not shown). Example features 75 may also comprise charge-blocking material 30, storage material 32, and charge-passage material 34 elevationally along second tiers 20 and first tiers 22. Materials 30, 32, and 34 (e.g., memory-cell materials) may be formed by, for example, deposition of respective thin layers thereof over stack 18 and within openings is stack 18 followed by planarizing such back at least to a top surface of stack 18 as shown. Another second tier 20 (FIG. 16) comprising material 24 may optionally be formed atop stack 18, with openings formed there-through corresponding in size and positions to openings 25 and that are filled with material 50 (e.g., polysilicon) to comprise part of features 75. Such another second tier 20 and openings there-through may be formed before or after forming corresponding openings in stack 18 and/or other parts of features 75 that are ultimately below material 75. Such another second tier 20 and/or material 50 may also be formed in memory array region 12 (not shown).

Operative channel-material strings 53ₓ (features 75) in memory array region 12 are shown as being in openings 25 and are arranged in groups or columns of staggered rows of four and five per row in array 12 and are arrayed in laterally-spaced memory-block regions 58 that will comprise laterally-spaced memory blocks 58 in a finished-circuitry construction. In this document, “block” is generic to include “sub-block”. Memory-block regions 58 and resultant memory blocks 58 (not yet shown) may be considered as being longitudinally elongated and oriented, for example along a first direction 55. Dummy channel-material strings 53_{z} (features 75) in horizontal area 14 are shown as being in openings 25 and are arranged in groups or columns of staggered rows in some regions of four and five per row and in other regions of three and four per row. Features 75/Strings 53ₓ and/or 53_{z} may be in alternate arrangement(s) and be of different construction(s).

By way of example, features 75/strings 53ₓ, 53_{z} are shown as comprising part of individual channel-material string constructions comprising charge-blocking material 30, storage material 32, and charge-passage material 34 that have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 is directly electrically coupled with conductor material 17 of conductor tier 16 at least in memory array region 12. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

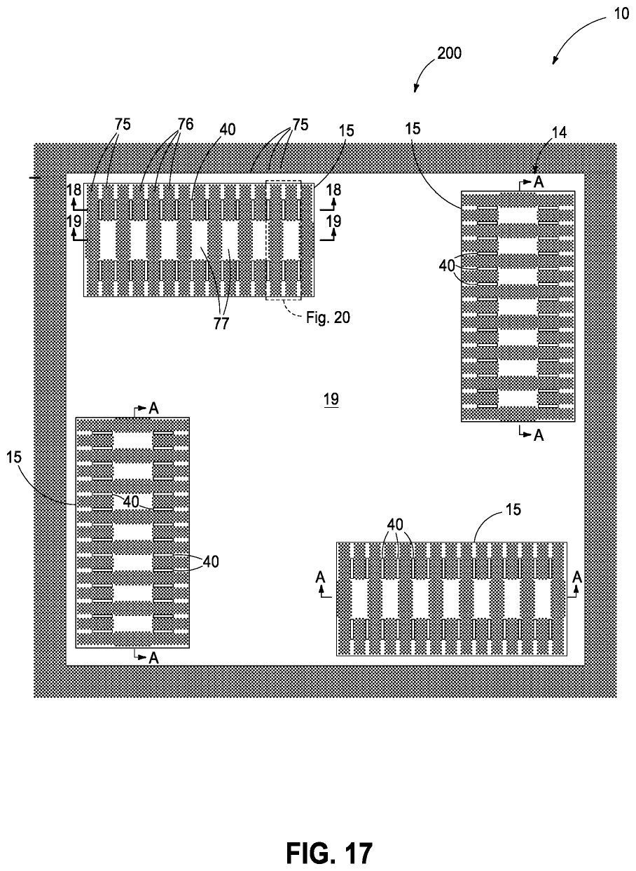

Referring to FIGS. 17-24, horizontally-spaced vertical slots 40 have been formed through uppermost (at least) of first and second tiers 22/20 of stack 18 in horizontal area 14 (e.g., in individual horizontal regions 15) of the registration mark or of the alignment mark that is being formed. Slots 40 may extend through stack 18 in horizontal area 14 (as shown) or only partially into stack 18 (not shown). Ideally, such are formed commensurate with forming analogous slots 40 in memory-array region 12 in die areas 100 as is shown (e.g., when forming the example memory circuitry), and slots 40 in regions 12 and 14 need not be the same size and/or shape relative one another.

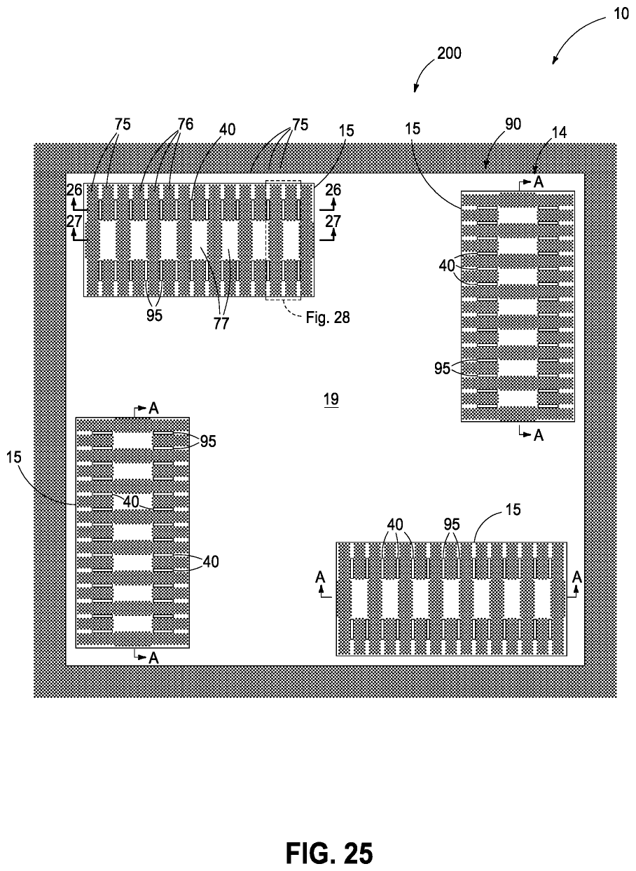

FIGS. 25-35 show replacing of sacrificial material 26 (not shown) with metal material 48 through horizontally-spaced slots 40, thus forming a mark 90 that is a registration mark or an alignment mark. In one embodiment, the registration mark or the alignment mark is fabricated as an alignment mark and in one embodiment as a registration mark. As an example, where sacrificial material 26 is silicon nitride, such can be isotropically selectively etched away through slots 40 using liquid or vapor H₃PO₄ as a primary etchant and other materials comprise one or more oxides or polysilicon. This can be followed by formation of metal material 48 through slots 40 into void space resulting from the removal of sacrificial material 26 and then removing remnant metal material 48 from slots 40. In one embodiment, for example in accordance with fabrication of memory circuitry, metal material 48 is conductive in the fabrication of control gate lines of memory circuitry that is within memory-array region 12.

FIGS. 25-35 also show, and in one embodiment, horizontally-spaced vertical slots 40 having been filled with intervening material 57 to form a vertical wall 95 in individual vertical slots 40. Intervening material 57 in memory-array region 12 may provide lateral electrical isolation (insulation) between immediately-laterally-adjacent memory blocks. Such may include one or more of insulative, semiconductive, and conducting materials and, regardless, may facilitate conductive tiers 22 in memory-array region 12 from shorting relative one another in a finished-circuitry construction. Example insulative materials are one or more of SiO₂, Si₃N₄, and Al₂O₃. Intervening material 57 in memory-array region 12 may include through-array vias (not shown).

A thin insulative liner (e.g., Al₂O₃ and not shown) may be formed before forming metal material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Metal material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36. In one embodiment and as shown with respect to the example “gate-last” processing, metal material 48 of conductive tiers 22 is formed after forming channel openings 25 and/or trenches 40. Alternately, the conducting material of the conductive tiers may be formed before forming channel openings 25 and/or trenches 40 (not shown), for example with respect to “gate-first” processing.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and metal material 48). Regardless, as an additional example, an interface of a storage material and conductive material of a control gate may be sufficient to function as a charge-blocking region in the absence of any separate-composition-insulator material 30. Further, an interface of metal material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Referring to FIGS. 36-39, after forming metal material 48 in horizontal area 14, first and second tiers 22/20 in scribe-line areas 200 are cut through to form individual die 85 (FIGS. 36 and 37) that individually comprise one of individual die areas 100. In one embodiment, the cutting may be through registration and/or alignment mark(s) 90 and individual die 85 may comprise remaining-scribe-line area 200 at edge(s) 99 of the individual die in the finished-circuitry construction. A remnant 90w of registration or alignment mark 90 may be in remaining-scribe-line area 200 in the finished-circuitry construction and comprises remaining of horizontally-spaced features 75.

Any other attribute(s) or aspect(s) as shown and/or described herein with respect to other embodiments may be used in the embodiments shown and described with reference to the above embodiments.

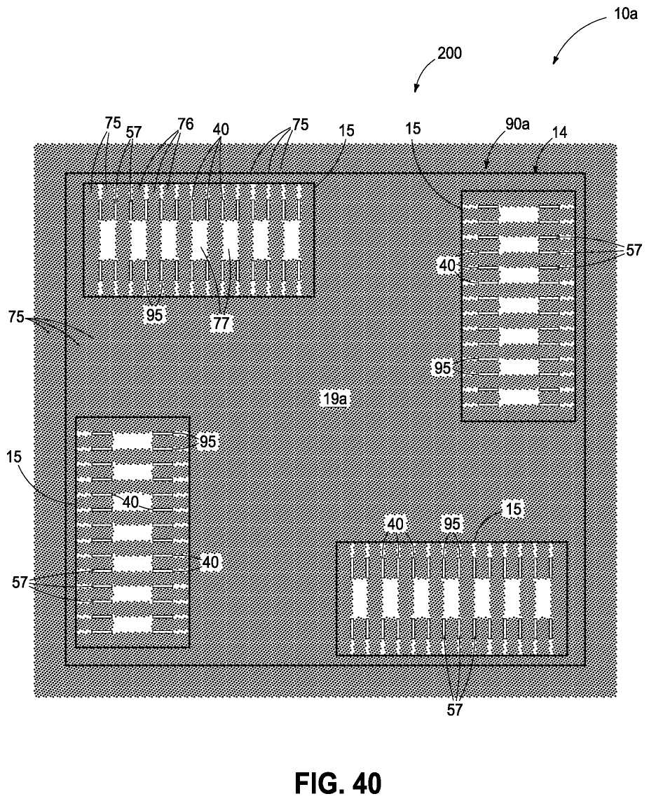

In one example embodiment and as shown, horizontal space 19 of a registration or alignment mark 90 is devoid of horizontally-spaced features 75 (FIGS. 7, 17, 25). FIG. 40 shows an alternate embodiment construction 10a. Like numerals from the above-described embodiments have been used where appropriate, with some construction differences being indicated with the suffix “a” or with different numerals. In construction 10a, registration or alignment mark 90a has its horizontal space 19a having horizontally-spaced features 75 therein. Further, and in one embodiment of such example, horizontally-spaced features 75 are arrayed in a horizontal pattern in sections 76 with such horizontal pattern being continuous in sections 76 and in and across horizontal space 19a. Any other attribute(s) or aspect(s) as shown and/or described herein with respect to other embodiments may be used.

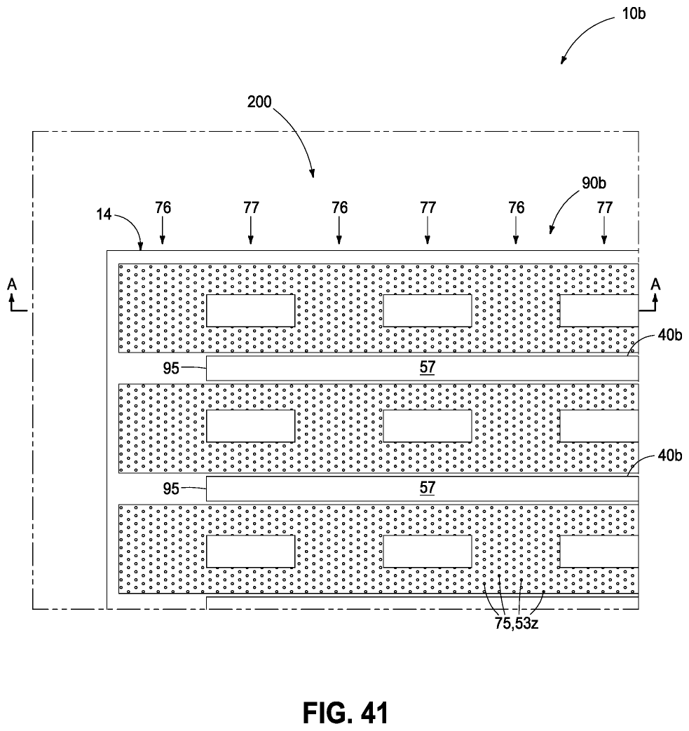

By way example, the embodiments depicted by FIGS. 17, 25, and 40 show slots 40 in mark 90/90a as being horizontally-parallel relative one another and horizontally-elongated orthogonal to the vertical cross-section referred to above with respect to gaps 77 where there are less, if any, such horizontally-spaced features than are in section 76. FIG. 41 shows an alternate example embodiment construction 10b. Like numerals from the above-described embodiments have been used where appropriate, with some construction differences being indicated with the suffix “b” or with different numerals. By way example, mark 90b comprises an alignment mark 90b or a registration mark 90b where slots 40b are horizontally-parallel relative one another and horizontally-elongated parallel to the subject vertical cross-section (e.g., a vertical cross-section as would be cut through line A-A in FIG. 41). Alternately, the slots may not be parallel relative one another and/or may not be horizontally-elongated orthogonal to the vertical cross-section and/or not be horizontally-elongated parallel to the subject vertical cross-section. Any other attribute(s) or aspect(s) as shown and/or described herein with respect to other embodiments may be used.

Various layers (e.g., silicon dioxide and silicon nitride) may be largely transparent to the incident optical radiation that is typically used in the scanning of alignment and registration marks. If features extending through those layers are not perfectly vertical, such can adversely impact x-y spatial determination from the scan. To preclude such, uppermost portions of material surrounding the features is typically formed to comprise radiation-opaque material, adding to cost and complexity in fabrication due to the added processing associated therewith. Fabrication as described herein may preclude use of such added processing.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, integrated circuitry (e.g., 10, 10a, 10b) comprises a die (e.g., 85) comprising remaining-scribe-line area (e.g., 200 in FIGS. 36 and 37) at an edge (e.g., 99) of the die. Operative circuitry (e.g., that comprising memory-cell strings 49) is in the die laterally-inward of the remaining-scribe-line area away from the edge of the die. A remnant (e.g., 90w) of a registration mark (e.g., 90, 90a, 90b ) or of an alignment mark (e.g., 90, 90a, 90b ) is in the remaining-scribe-line area. The remnant comprises horizontally-spaced features (e.g., 75) of the registration mark or of the alignment mark and that extend through vertically-alternating insulative-material tiers (e.g., 20) and metal-material tiers (e.g., 22) that are of different compositions relative one another. In one embodiment, the remnant is of a registration mark and in one embodiment is of an alignment mark. In one embodiment, the metal material of the metal-material tiers is conductive. In one embodiment, the remnant comprises horizontally-spaced vertical walls (e.g., 95) extending through uppermost of the insulative-material tiers and the metal-material tiers and in one such embodiment such vertical walls are horizontally-parallel relative one another. Any other attribute(s) or aspect(s) as shown and/or described herein with respect to other embodiments may be used.

In one embodiment, memory circuitry (e.g., 10, 10a, 10b) comprising strings (e.g., 49) of memory cells (e.g., 56) comprises a die (e.g., 85) comprising remaining-scribe-line area (e.g., 200) at an edge (e.g., 99) of the die. A stack (e.g., 18) comprising vertically-alternating first tiers (e.g., 22) and second tiers (e.g., 20) is in the die. Operative channel-material strings (e.g., 53x) of memory cells extend through the first tiers and the second tiers in a memory-array region (e.g., 12) of the die. First tiers (e.g., 22) and second tiers (e.g., 20) extend from the memory-array region into the remaining-scribe-line area. The first tiers are conductive in the memory-array region (at least). The second tiers are insulative. A remnant (e.g., 90w) of a registration mark (e.g., 90, 90a, 90b ) or of an alignment mark (e.g., 90, 90a, 90b ) is in the remaining-scribe-line area. The remnant comprises dummy channel-material strings (e.g., 53z) that extend through the first tiers and the second tiers. The second tiers of the remnant at least predominantly (more than 50% up to and including 100%) comprise metal material. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “ el evati onally -extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming integrated circuitry comprises forming a stack comprising vertically-alternating first tiers and second tiers. The first tiers comprise sacrificial material and the second tiers comprise non-sacrificial material that is of different composition from that of the sacrificial material. The stack extends from individual die areas to and across scribe-line area that is between immediately-adjacent of the individual die areas. The scribe-line area comprises a horizontal area in which a registration mark or an alignment mark is being fabricated. Horizontally-spaced features of the registration mark or of the alignment mark are simultaneously formed in the first tiers and the second tiers in the horizontal area and in the individual die areas. The horizontally-spaced features in the horizontal area are grouped in sections that are horizontally-separated by gaps in at least one vertical cross-section where there are less, if any, such horizontally-spaced features than are in the sections. Horizontally-spaced vertical slots are formed through uppermost of the first and second tiers of the stack in the horizontal area of the registration mark or of the alignment mark. Through the horizontally-spaced vertical slots, the sacrificial material is replaced with metal material. After the replacing, the first and second tiers in the scribe-line areas are cut through to form individual die that individually comprise one of the individual die areas.

In some embodiments, integrated circuitry comprising a die comprises remaining-scribe-line area at an edge of the die. Operative circuitry in the die is laterally-inward of the remaining-scribe-line area away from the edge of the die. A remnant of a registration mark or of an alignment mark is in the remaining-scribe-line area. The remnant comprises horizontally-spaced features of the registration mark or of the alignment mark and extends through vertically-alternating insulative-material tiers and metal-material tiers that are of different compositions relative one another.

In some embodiments, memory circuitry comprising strings of memory cells comprises a die comprising remaining-scribe-line area at an edge of the die. A stack is included that comprises vertically-alternating first tiers and second tiers in the die. Operative channel-material strings of memory cells extend through the first tiers and the second tiers in a memory-array region of the die. The first tiers and the second tiers extend from the memory-array region into the remaining-scribe-line area. The first tiers are conductive in the memory-array region. The second tiers are insulative. A remnant of a registration mark or of an alignment mark is in the remaining-scribe-line area. The remnant comprises dummy channel-material strings that extend through the first tiers and the second tiers. The second tiers of the remnant at least predominantly comprise metal material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming integrated circuitry, comprising:
forming a stack comprising vertically-alternating first tiers and second tiers, the first tiers comprising sacrificial material and the second tiers comprising non-sacrificial material that is of different composition from that of the sacrificial material, the stack extending from individual die areas to and across scribe-line area that is between immediately-adjacent of the individual die areas, the scribe-line area comprising a horizontal area in which a registration mark or an alignment mark is being fabricated;
simultaneously forming horizontally-spaced features of the registration mark or of the alignment mark in the first tiers and the second tiers in the horizontal area and in the individual die areas, the horizontally-spaced features in the horizontal area being grouped in sections that are horizontally-separated by gaps in at least one vertical cross-section where there are less, if any, such horizontally-spaced features than are in the sections;
forming horizontally-spaced vertical slots through uppermost of the first and second tiers of the stack in the horizontal area of the registration mark or of the alignment mark;
through the horizontally-spaced vertical slots, replacing the sacrificial material with metal material; and
after the replacing, cutting through the first and second tiers in the scribe-line areas to form individual die that individually comprise one of the individual die areas.

2. The method of claim 1 wherein the metal material is conductive.

3. The method of claim 1 comprising filling the horizontally-spaced vertical slots after the replacing and before the cutting to form a vertical wall in individual of the vertical slots.

4. The method of claim 1 wherein the horizontal area comprises horizontally-spaced horizontal regions of the registration mark or alignment mark and the horizontally-spaced features are formed in individual of the horizontal regions, the sections and the gaps being in the individual horizontal regions, the at least one vertical cross-section being with respect to a respective one of the individual horizontal regions, the horizontally-spaced vertical slots being formed in the individual horizontal regions.

5. The method of claim 4 comprising horizontal space between immediately-adjacent of the horizontal regions, the horizontal space being devoid of the horizontally-spaced features.

6. The method of claim 4 comprising horizontal space between immediately-adjacent of the horizontal regions, the horizontal space comprising the horizontally-spaced features therein, the horizontally-spaced features being arrayed in a horizontal pattern in the sections, the horizontal pattern of the horizontally-spaced features in the registration mark or the alignment mark being continuous in the sections and in and across the horizontal space.

7. The method of claim 1 wherein that which is fabricated is the registration mark.

8. The method of claim 1 wherein that which is fabricated is the alignment mark.

9. The method of claim 1 wherein the slots are horizontally-parallel relative one another and horizontally-elongated orthogonal to the vertical cross-section.

10. The method of claim 9 wherein that which is fabricated is the registration mark.

11. The method of claim 1 wherein the slots are horizontally-parallel relative one another and horizontally-elongated parallel to the vertical cross-section.

12. The method of claim 11 wherein that which is fabricated is the alignment mark.

13. The method of claim 1 wherein none of the horizontally-spaced features is in the gaps.

14. The method of claim 1 wherein,
the cutting is through the registration mark or the alignment mark;
the individual die comprise remaining of the scribe-line area at an edge of the individual die in a finished-circuitry construction; and
a remnant of the registration mark or of the alignment mark is in the remaining-scribe-line area in the finished-circuitry construction, the remnant comprising remaining of the horizontally-spaced features.

15. The method of claim 1 wherein,
the integrated circuitry comprises memory circuitry in a finished-circuitry construction;
the stack comprises a memory-array region within the individual die areas;
the horizontally-spaced features in the individual die areas comprise operative channel-material strings of memory cells extending through the first and second tiers in the memory-array region in the finished-circuitry construction; and
the horizontally-spaced features of the registration mark or the alignment mark comprise dummy channel-material strings.

16. Integrated circuitry comprising:
a die comprising remaining-scribe-line area at an edge of the die;
operative circuitry in the die laterally-inward of the remaining-scribe-line area away from the edge of the die; and
a remnant of a registration mark or of an alignment mark in the remaining-scribe-line area, the remnant comprising horizontally-spaced features of the registration mark or of the alignment mark and that extend through vertically-alternating insulative-material tiers and metal-material tiers that are of different compositions relative one another.

17. The integrated circuitry of claim 16 wherein the remnant is of the registration mark.

18. The integrated circuitry of claim 16 wherein the remnant is of the alignment mark.

19. The integrated circuit of claim 16 wherein the remnant comprises horizontally-spaced vertical walls extending through uppermost of the insulative-material tiers and the metal-material tiers.

20. Memory circuitry comprising strings of memory cells, comprising:
a die comprising remaining-scribe-line area at an edge of the die;
a stack comprising vertically-alternating first tiers and second tiers in the die, operative channel-material strings of memory cells extending through the first tiers and the second tiers in a memory-array region of the die, first tiers and the second tiers extending from the memory-array region into the remaining-scribe-line area, the first tiers being conductive in the memory-array region, the second tiers being insulative; and
a remnant of a registration mark or of an alignment mark in the remaining-scribe-line area, the remnant comprising dummy channel-material strings that extend through the first tiers and the second tiers, the second tiers of the remnant at least predominantly comprising metal material.
